(19) United States
(12) Patent Application Publication
(10) Pub. No.: US 2006/0021871 A1
(43) Pub. Date: Feb. 2, 2006

(54) Method for fabricating L10 phase alloy film

(75) Inventors: Po-Cheng Kuo, Taipei (TW); Huei-Li Huang, Taipei (TW); Jen-Hwa Hsu, Taipei (TW); Ching-Ray Chang, Taipei (TW); An-Cheng Sun, Taipei (TW); Sheng-Chi Chen, Taipei (TW); Chun-Yuan Chou, Taipei (TW); Chang-Tai Lee, Taipei (TW); Huang-Wei Chang, Taipei (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: Ching-Ray Chang, Taipei (TW)

(21) Appl. No.: 10/901,789

(22) Filed: Jul. 29, 2004

(51) Int. Cl. C23C 14/00; C23C 14/32

(52) U.S. Cl. 204/192.15; 204/192.12

(57) ABSTRACT

A method for fabricating an L1₀ alloy film is provided. The method includes steps of (a) providing a substrate; (b) heating the substrate as a preheated substrate at a first temperature ranged from 100° C. to 600° C. for a time period ranged from 5 minutes to 120 minutes, and then cooling the substrate to room temperature in the sputtering chamber; (c) depositing an alloy film on the preheated substrate; and (d) annealing the alloy film at a second temperature ranged from 200° C. to 500° C. to form the alloy film.

### FIELD OF THE INVENTION

This invention relates to a method for preparing an alloy film, and more particularly to a method for preparing an L1₀ alloy film at a low ordering temperature.

### BACKGROUND OF THE INVENTION

For increasing the magnetic recording density, the magnetic grain size must be reduced to small than 10 nm (D. N. Lambeth, E. M. T. Velu, G. H. Bellesis, L. L. Lee, and D. E. Laughlin, “Media for 10 Gb/in2 Hard Disk Storage: Issues and Status”, J. Appl. Phys., Vol. 79, pp. 4496-4501, 1996). However, the superparamagnetic limit problem and thermal instability will exist in such small magnetic grain. In order to overcome these problems, high magnetocrystalline anisotropy energy materials, FePt and CoPt, were developed due to the grain sizes of FePt and CoPt could be reduced to 3 nm and 6 nm, respectively.

At present, the CoCrPtM (M═Ni, Ta, W, B) alloy thin films are the most widely used in magnetic recording materials for the hard disk drive, due to their high coercivity (Hc>2800 Oe). However, these alloy thin films have two following disadvantages for the future higher recording density applications. (1) Grain size is comparatively larger, and (2) the coercivity is not sufficiently high enough. For example, if the areal recording density in magnetic recording would be increased, the grain size of the magnetic film must be correspondingly reduced (D. N. Lambeth, E. M. T. Velu, G. H. Bellesis, L. L. Lee, and D. E. Laughlin, “Media for 10 Gb/in² Hard Disk Storage: Issues and Status”, J. Appl. Phys., Vol. 79, pp. 4496-4501, 1996). However, reducing grain size will induce thermal instability problems. Therefore, it is necessary to use high magnetocrystalline anisotropy energy materials.

It is well known that ordered L1₀ FePt phase thin films have high coercivity Hc, good corrosion resistance and very high magnetocrystalline anisotropy energy (Ku ˜7×10⁷ erg/cm³). However, the as-deposited FePt film is magnetically soft disordered face-centered-cubic phase. The high coercivity film will be obtained by the high temperature annealing treatment or the substrate heating to transform the fcc FePt phase into the magnetically hard ordered face-centered-tetragonal L1₀ FePt phase. This ordering temperature is usually higher than 500° C. These had been dicussed several years ago. (K. R. Coffey, M. A. Parker, and J. K. Howard, “High Anisotropy L1₀ Thin Films for Longitudinal Recording”, IEEE Transactions on Magnetics, Vol. 31, No. 6, November 1995, pp. 2737-2739.) The grain size was increased in such high annealing treatment and these films have shown rather poor recording properties, in particular a low signal-to-noise ratio. In addition, the high-temperature annealing process is not compatible with existing magnetic recording media fabrication processes.

In order to overcome these problems, some methods have been developed to reduce the ordering temperature of FePt film, such as the addition of a third element (T. Maeda, A. Kikitsu, T. Kai, T. Nagase, H. Aikawa, and Jun-ichi Akiyama, IEEE Trans. Magn., Vol. 38, 2002 pp. 2796), multilayering (T. Seki, T Shima, K. Takanashi, Y. Takashi, and E. Matsubara, Appl. Phys. Lett, Vol. 82, 2003, pp. 2461-1463), ion irradiation (Chin-Huang Lai, Cheng-Han Yang, and C. C. Chiang, Appl. Phys. Lett, Vol. 83, 2003, pp. 4550-4552), and introduction of the underlayer. (Yu-Nu Hsu, Sangki Jeong, David E. Laughlin and David N. Lambeth, J. Appl. Phys., Vol. 89, 2001, pp. 7068-7070). Most of these processes are complicated or cause high cost.

In order to overcome the disadvantages of FePt alloy thin films described above, the present invention provides the low ordering temperature FePt and FePtX (or CoPt and CoPtX) thin film with good magnetic properties for higher density magnetic recording media applications. In according to the present invention, since the ordering temperature is lower than 400° C., the grain growth of the magnetic films is limited. Accordingly, the magnetic grain size can be reduced and the recording density of the film can be increased.

### SUMMARY OF THE INVENTION

It is an aspect of the present invention to fabricate low ordering temperature L1₀ FePt phase magnetic thin films for high-density magnetic recording media applications.

Polycrystalline FePt alloy thin films were prepared by dc magnetron sputtering on pre-heat-treatment substrates. The film thickness was varied from 10 to 200 nm. After suitable post-annealed and furnace cooling, it was found that the ordering temperature from as-deposited magnetic soft fcc FePt phase to magnetic hard fct L1₀ FePt phase could be reduced to about 300° C. The in-plane coercivity of the films was increased rapidly as annealing temperature is increased from 300° C. to 400° C. After annealing at 400° C. for 60 min., the in plane coercivity of FePt thin film with film thickness of 100 nm is 10 kOe, Ms is 580 emu/cm³, and grain size is about 12 nm.

The above aspects and advantages of the present invention will become more readily apparent to those ordinarily skilled in the art after reviewing the following detailed description and accompanying drawings, in which:

### BRIEF DESCRIPTION OF THE DRAWINGS

FIGS. 1(a) and 1(b) are SEM images respectively showing morphologies of natural-oxidized silicon wafer substrate surface with and without 300° C. pre-heat-treatment before depositing FePt thin film according to the preferred embodiment of the present invention;

FIGS. 2(a) and 2(b) are charts respectively showing AES depth profile analysis of 400° C. annealed with substrate pre-heat-treatment, and without substrate pre-heat-treatment according to the preferred embodiment of the present invention;

FIGS. 3(a)-3(c) are TEM bright field images respectively showing electron diffraction patterns of the as-deposited FePt film, the film after being annealed at 300° C. for 1 hour, and the film after being annealed at 350° C. according to the preferred embodiment of the present invention;

FIG. 4 is a chart showing X-ray diffraction patterns of the FePt thin films which annealed at various temperatures according to the preferred embodiment of the present invention;

FIG. 5 is a chart showing the relationship between the in-plane coercivity (Hc_{//}) and the annealing temperature of the FePt films with different thickness according to the preferred embodiment of the present invention;

FIG. 6 is a chart showing the relationship between the saturation magnetization (Ms) and the annealing temperature of the FePt films with different thickness according to the preferred embodiment of the present invention;

FIG. 7 is a chart showing the M-H loop of the annealed FePt film according to the preferred embodiment of the present invention; and

FIG. 8 is a chart showing the average grain sizes of the FePt films with different thickness as a function of annealing temperature according to the preferred embodiment of the present invention.

### DETAILED DESCRIPTION OF THE PREFERRED EMBODIMENT

The invention is described more specifically with reference to the following embodiments. It is to be noted that the following descriptions of preferred embodiments of this invention are presented herein for the purpose of illustration and description only; it is not intended to be exhaustive or to be limited to the precise form disclosed.

The present invention provides a method for fabricating an L1₀ alloy film. The method includes steps of (a) providing a substrate; (b) heating the substrate as a preheated substrate at a first temperature ranged from 100° C. to 600° C. for a time period ranged from 5 minutes to 120 minutes, and then cooling the substrate down to the room temperature in the sputtering chamber; (c) depositing an alloy film on the preheated substrate; and (d) annealing the alloy film at a second temperature ranged from 200° C. to 500° C. to form the L1₀ alloy film. The substrate is made of a material selected from a group consisting of a silicon wafer, a silicon, a silicon nitride, a glass, a quartz glass, an MgO and an Al—Mg alloy. Preferably, the step (b) is performed at the first temperature ranged from 200° C. to 300° C. for the time period ranged from 30 minutes to 90 minutes. The step (b) is initiated at a first base pressure lower than 10⁻⁶ Torr. The step (c) is initiated at a second base pressure lower than 5×10⁻⁷ Torr. The step (c) is performed by one of a DC magnetron sputtering and an RF magnetron sputtering, wherein a sputtering argon pressure ranged from 0.3 to 30 mTorr. The step (d) further includes a step of encapsulating the alloy film in a quartz tube before annealing the alloy thin film, or the alloy film is in-situ annealed in the step (d). In accordance with the present invention, the alloy film is made of a first element being one of Co and Fe, a second element being one of Pt and Pd, and a third element selected from a group consisting of C, Cr, Ti, Ta, W, Au, Ag, Mn, Nb, Zr, Mo, V, Cu and B. The second element is in a range from about 40 to 60 atomic percents of the alloy film. The third element is in a range from about 0.001 to 10 atomic percents of the alloy film. In accordance with the present invention, the fabricated L1₀ alloy film has an L1₀ phase with Ms>375 emu/cm³ and Hc>2000 Oe.

The present invention is further illustrated as follows. Single layer polycrystalline FePt alloy thin film is deposited on preheated nature-oxidized silicon wafer or other preheated substrates by DC magnetron sputtering at room temperature. Before sputtering FePt film, the substrate is preheated at 300° C. for 1 hour in order to burn out the vapor, N₂ and CO₂ adhered on the substrate, wherein the substrate is originally exposed to air. Therefore, the substrate surface is cleaned and the oxygen content in SiOx the nature-oxidized substrate is reduced. The preheated substrate is cool down to the room temperature in the sputtering chamber, and then the single polycrystalline FePt alloy thin film is deposited on the substrate. The as-deposited FePt films have soft magnetic fcc γ-FePt grains. After post-annealing in vacuum, the films have hard magnetic fct L1₀ FePt phase.

The FePt thin films of this invention are prepared by the conventional magnetron sputtering system with a DC power supply, and then post-annealed (or in-situ annealing) in vacuum. The substrate was rotated during sputtering in order to get uniform film thickness and composition. Three types of FePt targets including (1) FePt alloy target, (2) A mosaic target consisting of high purity iron disk (99.99%) overlaid with high purity platinum pieces (99.99%) and (3) Co-sputtering of Fe target and Pt target are used in the present invention. The composition of the FePt thin film is preferred in the range from 40 to 60 atomic percent Pt. For optimized magnetic properties, a more narrow range from 45 to 55 atomic percent Pt is preferred. The base pressure in the sputtering chamber is lower than 5×10⁻⁷ Torr. Before sputtering FePt film, the substrate was preheated at 300° C. for 1 hour in order to clean the substrate surface and reduce the oxygen content in SiOx which is adhered on the nature-oxidized substrate. The preheated substrate is cool down to the room temperature in the sputtering chamber. After the high purity argon gas (99.9995%) is introduced, the argon pressure P_{Ar} is set at 0.3˜30 mTorr. Sputtering rates of the FePt are dependent on P_{Ar}. In order to get good magnetic properties, the P_{Ar} ranged from 5 to 15 mTorr is preferred. The applied DC power density is set at 1.25 W/cm². The deposition rate of FePt is about 0.3 nm/s. The sputtering conditions for the FePt thin films are shown in Table 1.

TABLE 1
The operating conditions for co-sputtering granular FePt thin film

| Substrate temperature(Ts) | Room temperature | |
|---|---|---|
| DC power density | 1.25 | W/cm² |
| Base vacuum | <5 × 10⁻⁷ | Torr |
| Distance between substrate and target | 6 | cm |
| Argon pressure | 10 | mTorr |
| Sputtering rate of the film(average) | ˜0.3 | nm/sec. |
| Argon flow rate | 10 | ml/min |

According to the present invention, two types of annealing processes are used. One is post-annealing in vacuum (<1×10⁻⁶ Torr) and then furnace cooling to room temperature, and the other is in-situ annealing in chamber (the vacuum is about 10⁻⁷ Torr) and then furnace cooling to room temperature.

The efficacy and advantages of the present invention are further illustrated as follows.

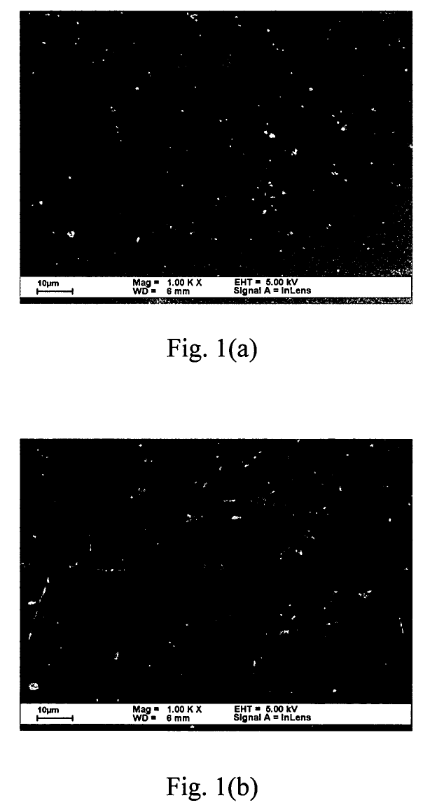

The initial temperature of the natural-oxidized silicon wafer substrate is at the room temperature. After the sputtering chamber is evacuated to about 10⁻⁷ Torr, the substrate is heated to 300° C. for 1 hour and then the substrate is cooled by the furnace cooling to the room temperature before depositing FePt thin film thereon. The vapor, N₂ and CO₂ adhered on the substrate that come from the air during being exposed to air, are burn out and the substrate surface is cleaned after heating the substrate. Please refer to FIGS. 1(a) and 1(b), which are the SEM images respectively showing the morphology of natural-oxidized silicon wafer substrate surface with and without 300° C. preheating before depositing FePt thin film. There are many white salients shown in the FIG. 1(a) and few salients shown in the FIG. 1(b). This means that the preheated substrate has a clearer surface than the substrate without being preheated.

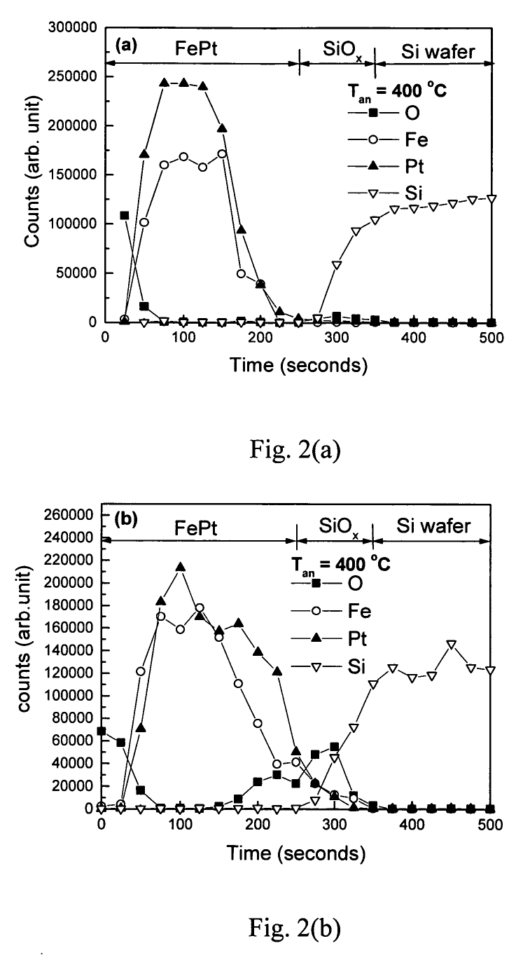

After the preheated substrate is cooled to room temperature and the base pressure of the sputtering chamber is evacuated to about 5×10⁻⁷ Torr, a FePt thin film is deposited on the preheated substrate. According to the present invention, the Ar pressure is maintained at about 10 mTorr during sputtering the FePt thin film. The deposition rate of the FePt film is shown in Table 1. The as-deposited film is encapsulated in a quartz tube and post-annealed in vacuum at various temperatures for 1 hour, and then be cooled by the furnace cooling. Please refer to FIGS. 2(a) and 2(b), which are charts respectively showing the AES depth profile analysis of the FePt film with substrate pre-heat-treatment and without substrate pre-heat-treatment after being post-annealed at 400° C. for 1 hour. From FIG. 2(a), we can see that there is no oxidation at the interface between substrate and FePt film. Referring to FIG. 2(b), it is shown that the high oxygen content is distributed at the interface between substrate and FePt film. The oxygen at the interface will diffuse into the FePt thin film and reduce magnetic properties during annealing. Therefore, the advantage of substrate pre-heat-treatment is obvious.

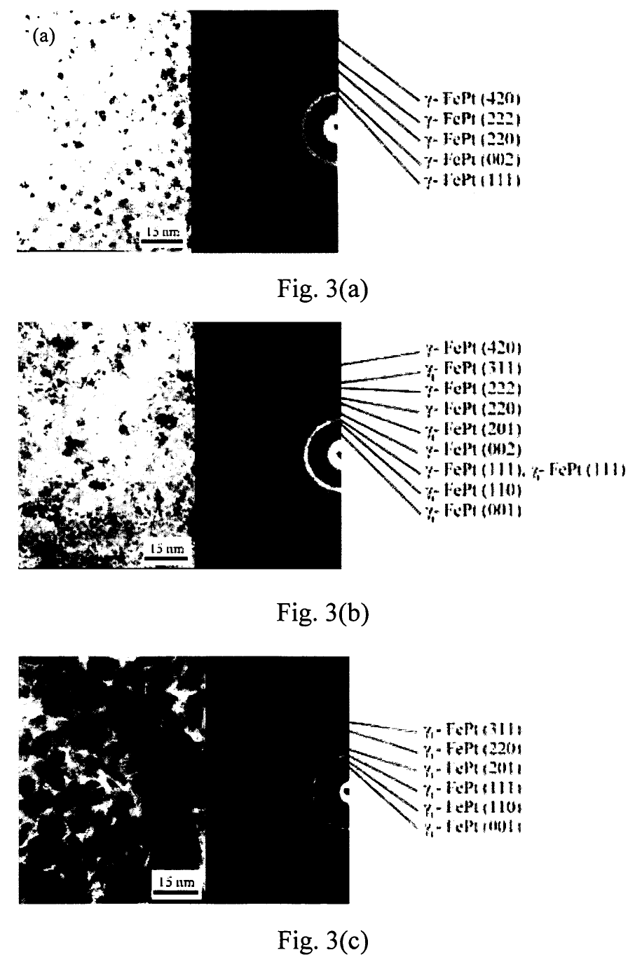

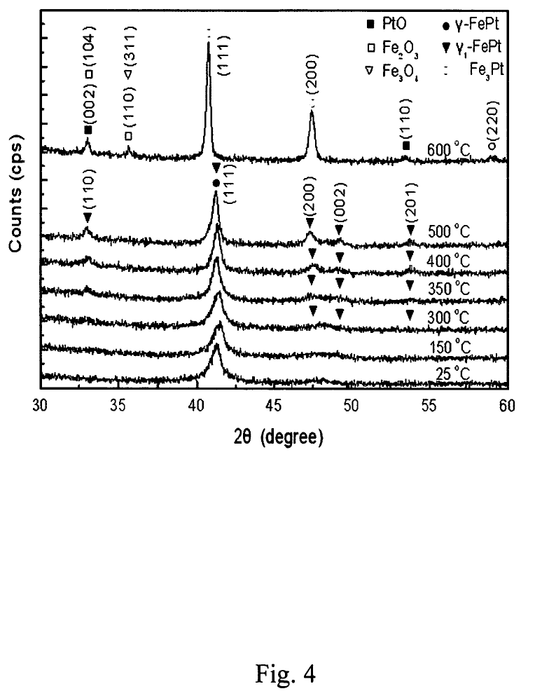

Please refer to FIGS. 3(a)-3(c), which are TEM bright field images respectively showing electron diffraction patterns of the as-deposited FePt film, the film after being annealed at 300° C. for 1 hour and the film after being annealed at 350° C. It is shown that the as-deposited FePt films has disordered fcc γ-FePt phase. After annealed at 300° C., some ordered γ₁-FePt phase (i.e., L1₀ fct phase) is observed. The L1₀ fct phase is completely formed after 350° C. annealing. FIG. 4 is a chart shoowing the X-ray diffraction patterns of the Fe₅₂Pt₄₈ thin films which are annealed at various temperatures. The film thickness is kept at 100 nm. It is to be noted that the fcc FePt phase is dominated when Tₐₙ is <300° C. and the L1₀ FePt phase appears as Tₐₙ=300° C. The superllattice peaks (110), (111), (200), (002), and (201) of L1₀ FePt phase are observed. This means that the order-disorder transformation temperature of the film starts at about 300° C. The superllattice peaks of L1₀ FePt phase are more clear as Tₐₙ=400° C. The superllattice peaks of L1₀ FePt phase are disappeared as Tₐₙ is increased to 600° C. and some Fe₃Pt, PtO, Fe₂O₃, and Fe₃O₄ phases appear at this temperature. It is difficult to identify the peaks of PtO(002) and Fe₂O₃(104), and Fe₂O₃(110)/Fe₃O₄(311) peakes since their d-spacings are very close.

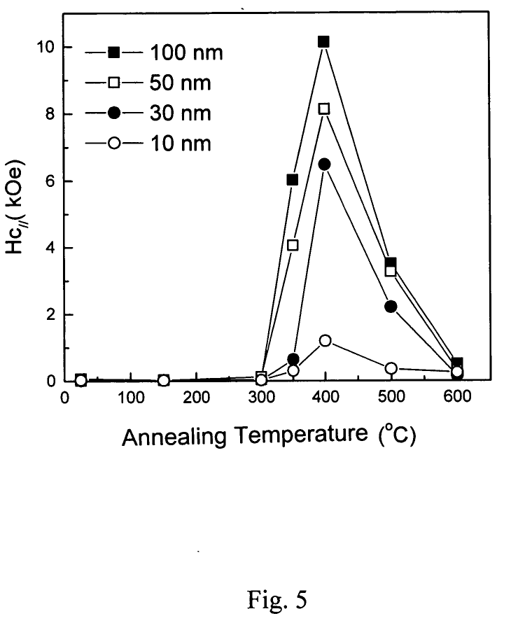

Please refer to FIG. 5, which is a chart showing the relationship between the in-plane coercivity (Hc_{//}) and the annealing temperature (Tₐₙ) of various FePt films. Thickness of the FePt film is varied from 10 nm to 100 nm. It is shown that the film has very low Hc_{//}(<100 Oe) as Tₐₙ≦300° C. The Hc_{//} value increases rapidly as Tₐₙ is increased from 300° C. to 400° C. Then, it decreases abruptly as Tₐₙ>400° C. The maximum Hc_{//} value of the film is occurred at Tₐₙ˜400° C. to be about 10 kOe, wherein the film thickness is 100 nm. The variation of Hc_{//} value is small when the film thickness is larger than 100 nm. When Tₐₙ<300° C., Hc_{//} of the film is low (<100 Oe) due to the film having the soft magnetically fcc phase. As Tₐₙ>300° C., the rapid increase of Hc_{//} is due to the rapid increase of the amount of fct L1₀ FePt phase. The Hc_{//} value is smaller than 4 kOe when Tₐₙ>500° C. since the film is oxidized and some chemical reactions is performed in the FePt film when Tₐₙ>500° C.

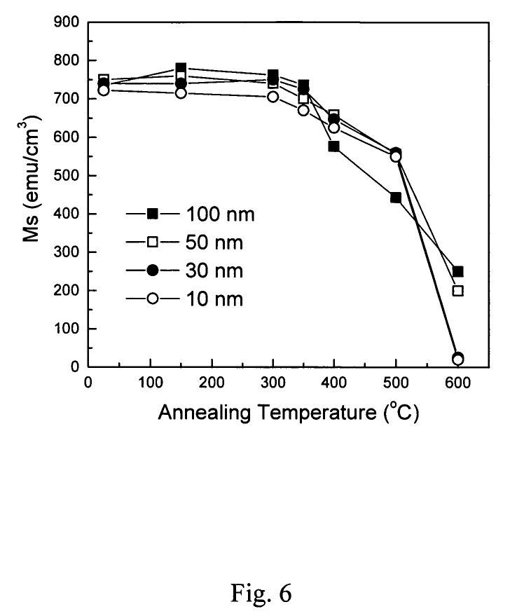

FIG. 6 is a chart showing the relationship between the saturation magnetization (Ms) and the annealing temperature of various FePt films. The film thickness is varied from 10 nm to 100 nm. When Tan<300° C., the Ms value of the film is kept at about the same as that of as-deposited film. This means that the film isn't oxidized and film structure is still soft magnetic fcc phase as Tan<300° C. When Tan increases from 300° C. to 500° C., the Ms value decreases slowly. This is due to the disordered FePt phase transformed gradually into the ordered L10 FePt phase since the Ms value of ordered L10 FePt phase is lower than that of disordered FePt phase. When Tan>500° C., Ms value of the film decreases abruptly. This is due to the oxidization of FePt film and the formation of some Fe₂O₃, Fe₃O₄, PtO, and Fe3Pt phases therefor.

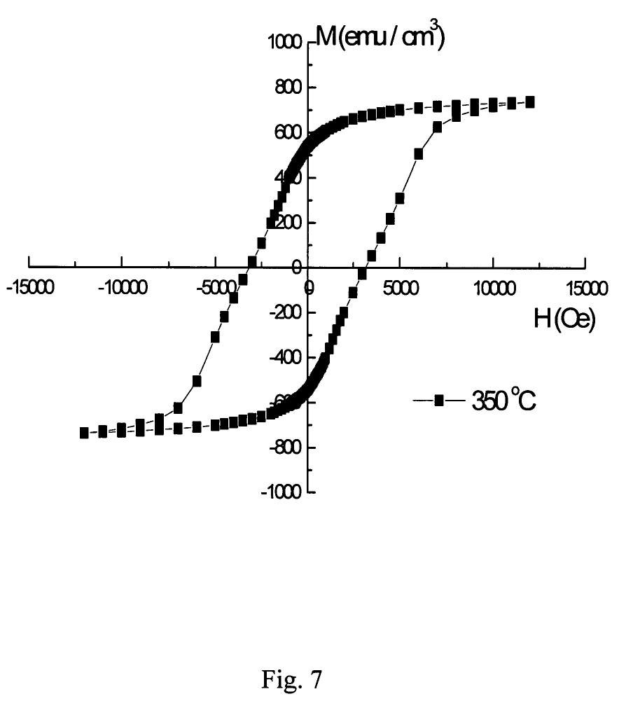

FIG. 7 is a chart showing the M-H loop of the annealed FePt film. The applied field is parallel to the film plane. The sputtering conditions and the FePt composition are the same as those indicated in Table 1. The annealing condition is performed at 350° C. for 1 hour, and then the furnace cooling is performed. It is shown that the Hc value is 3200 Oe and the Ms value is about 736 emu/cm³.

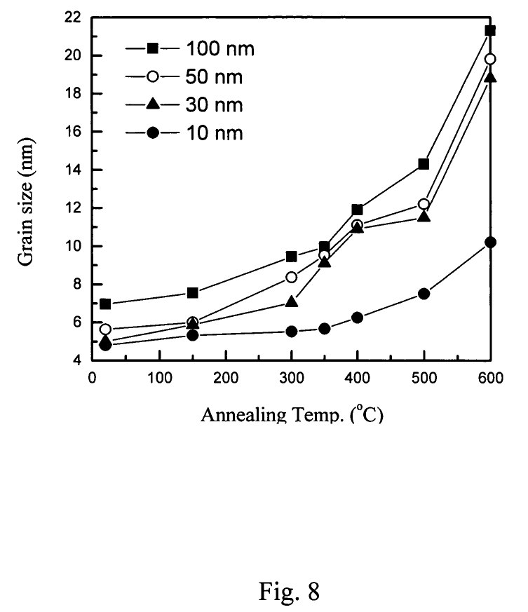

FIG. 8 is a chart showing the average grain size of various FePt films as a function of annealing temperature. The sputtering conditions and the FePt composition are the same as those indicated in Table 1. The grain sizes of the film are calculated from Scherrer formula by using the X-ray diffraction peaks of disordered FePt (111) and ordered L1₀ FePt (111). The grain size of the film is increased with increasing annealing temperature. After annealed at 400° C., average grain size of the film with the thickness of 100 nm is about 12 nm.

The differences between the present invention and the prior art can be summarized as follows.

(1) In the prior art, the preheating process for the substrate have never been used in FePt thin films, wherein the FePt thin films are used for the high-density magnetic recording media.

(2) In the present invention, in order to obtain L1₀ ordered FePt phase at low temperature, the substrate must be preheated before depositing the FePt thin film thereon.

(3) In the present invention, the transformation of disorder fcc FePt to fct L1₀ FePt phase is started at about 300° C., so that the present invention provides the samller FePt grain size and is suitable for high-density magnetic recording media manufacture.

(4) In order to obtain L1₀ ordered FePt phase at low temperature, the furnace cooling after annealing have to be used according to the present invention.

(5) In the present invention, the L1₀ ordered FePt phase is obtained by the phase transformation reaction, i.e. a soft magnetic γ-FePt phase is formed preliminary, and then it is transferred to a hard magnetic L1₀ γ₁-FePt phase after an annealing treatment.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for fabricating an L1₀ alloy film, comprising steps of:
(a) providing a substrate;
(b) heating said substrate as a preheated substrate at a first temperature ranged from 100° C. to 600° C. for a time period ranged from 5 minutes to 120 minutes;
(c) depositing an alloy film on said preheated substrate; and
(d) annealing said alloy film at a second temperature ranged from 200° C. to 500° C. to form said L1₀ alloy film.

2. The method according to claim 1, wherein said substrate is made of a material selected from a group consisting of a silicon wafer, a silicon, a silicon nitride, a glass, a quartz glass, a coming glass, an MgO and an Al—Mg alloy.

3. The method according to claim 1, wherein said step (b) is performed at said first temperature ranged from 200° C. to 300° C. for said time period ranged from 30 minutes to 90 minutes.

4. The method according to claim 1, wherein said step (b) is initiated at a first base pressure lower than 10⁻⁶ Torr.

5. The method according to claim 1, wherein said step (c) is initiated at a second base pressure lower than 5×10⁻⁷ Torr.

6. The method according to claim 1, wherein said step (c) is performed by one of a DC magnetron sputtering and an RF magnetron sputtering.

7. The method according to claim 5, wherein said step (c) is performed at a sputtering argon pressure ranged from 0.3 to 30 mTorr.

8. The method according to claim 1, wherein said step (d) comprises a step of encapsulating said alloy film in a quartz tube before annealing said alloy thin film.

9. The method according to claim 1, wherein said alloy film is in-situ annealed in said step (d).

10. The method according to claim 1, wherein said alloy film is made of a first element being one of Co and Fe, a second element being one of Pt and Pd and a third element selected from a group consisting of C, Cr, Ti, Ta, W, Au, Ag, Mn, Nb, Zr, Mo, V, Cu and B.

11. The method according to claim 10, wherein said second element is in a range from about 40 to 60 atomic percents of said alloy film.

12. The method according to claim 10, wherein said third element is in a range from about 0.001 to 10 atomic percents of said alloy film.

13. The method according to claim 1, wherein said L1₀ alloy film has an L1₀ phase with Ms>375 emu/cm³ and Hc>2000 Oe.

14. A method for fabricating an L1₀ alloy thin film, comprising step of:
(a) providing a substrate;
(b) heating said substrate as a preheated substrate at a first temperature ranged from 100° C. to 600° C. for a time period ranged from 5 minutes to 120 minutes;
(c) depositing an alloy film on said preheated substrate; and
(d) annealing said alloy film to form said L1₀ alloy film.

15. The method according to claim 14, wherein said step (d) is performed at a second temperature ranged from 200° C. to 500° C.

16. The method according to claim 1, wherein said alloy thin film is made of a first element being one of Co and Fe, a second element being one of Pt and Pd, and a third element selected from a group consisting of C, Cr, Ti, Ta, W, Au, Ag, Mn, Nb, Zr, Mo, V, Cu and B.

17. The method according to claim 16, wherein said second element is in a range from about 40 to 60 atomic percent of said alloy film.

18. The method according to claim 16, wherein said third element is in a range from about 0.001 to 10 atomic percent of said alloy film.

19. The method according to claim 14, wherein said L1₀ alloy thin film has an L1₀ phase with Ms>375 emu/cm³ and Hc>2000 Oe.

20. An L1₀ alloy film fabricated by said method as claimed in claim 14, comprising properties of:
Ms>375 emu/cm³ and Hc>2000 Oe.
